(19) United States
(12) Patent Application Publication
(10) Pub. No.: US 2014/0315392 A1
(43) Pub. Date: Oct. 23, 2014

(54) COLD SPRAY BARRIER COATED COMPONENT OF A PLASMA PROCESSING CHAMBER AND METHOD OF MANUFACTURE THEREOF

(71) Applicant: LAM RESEARCH CORPORATION, Fremont, CA (US)

(72) Inventors: Lin Xu, Katy, TX (US); Hong Shih, Walnut, CA (US); Anthony Amadio, San Mateo, CA (US); Rajinder Dhindsa, San Jose, CA (US); John Michael Kerns, Livermore, CA (US); John Daugherty, Fremont, CA (US)

(73) Assignee: Lam Research Corporation, Fremont, CA (US)

(21) Appl. No.: 13/867,522

(22) Filed: Apr. 22, 2013

(51) Int. Cl. H01L 21/67

(52) U.S. Cl. CPC H01L 21/67017
USPC 438/710; 118/723 R; 427/58; 156/345.48; 156/345.34; 438/758; 428/457; 428/662; 428/665; 428/660; 428/680; 428/650; 428/673; 428/674; 428/685; 428/681; 428/668; 428/336

(57) ABSTRACT

A cold spray barrier coated component of a semiconductor plasma processing chamber comprises a substrate having at least one metal surface wherein a portion of the metal surface is configured to form an electrical contact. A cold spray barrier coating is formed from a thermally and electrically conductive material on at least the metal surface configured to form the electrical contact of the substrate. Further, the cold spray barrier coating may also be located on a plasma exposed and/or process gas exposed surface of the component.

### FIELD OF THE INVENTION

The present invention relates to components of semiconductor plasma processing chambers, and more specifically for a barrier coating for components of semiconductor plasma processing chambers.

### BACKGROUND

In the field of semiconductor material processing, semiconductor plasma processing chambers including vacuum processing chambers are used, for example, for etching and deposition, such as plasma etching or plasma enhanced chemical vapor deposition (PECVD) of various materials on substrates. Some of these processes utilize corrosive and erosive process gases and plasma in such processing chambers. It is desirable to minimize chamber component wear, and particle and/or metal contamination of substrates processed in the chambers. Accordingly, it is desirable that plasma-exposed components of such apparatuses be resistant to corrosion when exposed to such gases and plasma.

### SUMMARY

Disclosed herein is a cold spray barrier coated component of a semiconductor plasma processing chamber. The cold spray barrier coated component of a semiconductor plasma processing chamber comprises a substrate having at least one metal surface wherein a portion of the metal surface is configured to form an electrical contact, and a cold spray barrier coating formed from a thermally and electrically conductive material on at least the metal surface configured to form the electrical contact. Further, the cold spray barrier coating may be on a portion of the metal surface exposed to plasma and/or process gas.

Also disclosed herein is a process for cold spray barrier coating at least one metal surface forming an electrical contact of a component of a semiconductor plasma processing chamber. The process for cold spray barrier coating the electrical contact of a component of a semiconductor plasma processing chamber comprises cold spraying an electrically conductive cold spray barrier on at least portion of at least one metal surface of a substrate, wherein the portion of the metal surface is configured to form an electrical contact.

Further disclosed herein is a semiconductor plasma processing apparatus. The semiconductor plasma processing apparatus, comprises a plasma processing chamber in which semiconductor substrates are processed. The apparatus further comprises a process gas source in fluid communication with the plasma processing chamber for supplying a process gas into the plasma processing chamber, and an RF energy source is adapted to energize the process gas into the plasma state in the plasma processing chamber. The semiconductor plasma processing apparatus comprises at least one cold spray barrier coated component.

Also disclosed herein is a method of plasma processing a semiconductor substrate in a semiconductor plasma processing apparatus comprising at least one cold spray barrier coated component. The method comprises supplying the process gas from the process gas source into the plasma processing chamber, applying RF energy to the process gas using the RF energy source to generate plasma in the plasma processing chamber, and plasma processing a semiconductor substrate in the plasma processing chamber.

### BRIEF DESCRIPTION OF THE DRAWING FIGURES

FIG. 1 illustrates a cross section of a cold spray barrier coated component of a plasma processing chamber.

FIG. 2 illustrates an exemplary embodiment of a capacitively coupled plasma etching chamber in which embodiments of the cold spray barrier coated components can be installed.

FIG. 3 illustrates an embodiment of cold spray barrier coated components.

FIG. 4 illustrates an embodiment of cold spray barrier coated components.

### DETAILED DESCRIPTION

Disclosed herein is a component of a semiconductor plasma processing chamber comprising an electrically conductive barrier coating, wherein the barrier coating is formed with a cold spray barrier coating technique and is corrosion resistant. The semiconductor plasma processing chamber preferably includes a vacuum chamber, and may be a plasma etching or deposition chamber (herein referred to as “plasma chamber”) of a semiconductor plasma processing apparatus. In the following description, numerous specific details are set forth in order to provide a thorough understanding of the present embodiments. It will be apparent, however, to one skilled in the art that the present embodiments may be practiced without some or all of these specific details. In other instances, well known process operations have not been described in detail in order not to unnecessarily obscure the present embodiments.

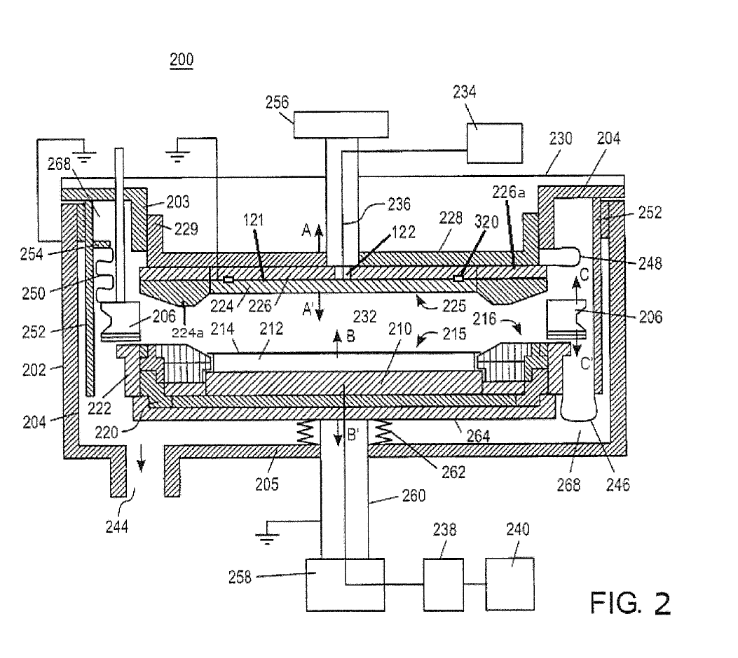

Components described herein include a substrate having at least one metal surface, such as an aluminum or aluminum alloy substrate, and an electrically conductive cold spray barrier coating on a portion of the metal surface which is configured to form an electrical contact of the substrate. The portion of the metal surface which is configured to form an electrical contact of the substrate may be a surface of the component configured to mate with a surface of an adjacent component (i.e. mating surface). The electrically conductive cold spray barrier coating may additionally be formed on a plasma exposed and/or process gas exposed metal surface of the substrate. The component to be cold spray barrier coated is preferably an aluminum or aluminum alloy electrical contact within the plasma chamber, such as mating surfaces between a gas distribution plate 226 and an electrode 224 (see FIG. 2) which form electrical contacts therebetween. The cold spray barrier coating can be formed from niobium, tantalum, tungsten, tungsten carbide, molybdenum, titanium, zirconium, nickel, cobalt, iron, chromium, aluminum, silver, copper, stainless steel, WC-Co, or alloys or mixtures thereof. The cold spray barrier coating can also be on a metal surface exposed to plasma and/or process gas such as an exterior surface, or an interior surface that defines a hole, cavity, or aperture. The cold spray barrier coating can be applied on one or more, or on all, exterior and/or interior surfaces of the metal substrate.

During plasma processing, such as an etching processes, process gases can be halogen-containing species, e.g., CₓF_{y}, CₓH_{y}F_{z}, HBr, NF₃, HCl, SiCl₄, Cl₂, and BCl₃ (wherein x≧1, y≧1, and z≧0), which are corrosive with respect to aluminum and aluminum alloy surfaces. Therefore, the cold spray barrier coating may be preferably applied to aluminum or aluminum alloy surfaces. Such application may be in the form of a replaceable dense aluminum cold spray barrier coating, or more preferably a corrosion resistant cold spray barrier coating formed from a material, such as tantalum, on aluminum or aluminum alloy surfaces. Tantalum may be preferred due to its resistance to halogen corrosion and its thermal and electrical properties.

Components which include the electrically conductive cold spray barrier coating can be used in apparatuses for performing various processes including plasma etching of semiconductor substrates and deposition of materials (e.g., ALD, PECVD and the like) used for manufacturing various substrates including, e.g., semiconductor wafers, flat panel display substrates, and the like. Depending on the type and construction of an apparatus, the component(s) having at least one metal surface wherein a portion of the metal surface is configured to form an electrical contact, which is to be cold spray coated, can be, e.g., chamber walls, chamber liners, baffles, gas distribution plates, gas distribution rings, substrate supports, edge rings, gas nozzles, fasteners, shrouds, confinement rings, gaskets, RF straps, electrically conductive connecting members, and the like. For example the components may include an aluminum or aluminum alloy surface wherein the surface is exposed to process gas and/or plasma wherein a portion of the aluminum or aluminum alloy surface is configured to form a contact with another component such that electrical current (either RF or DC) may pass through both components during plasma processing of a semiconductor wafer. The cold spray barrier coating may be applied to the exposed aluminum or aluminum alloy surface of the component and the electrical contact portion of said component, such that the surface may exhibit a barrier coating (e.g. an aluminum cold spray barrier coating), or corrosion resistant barrier coating (e.g. a tantalum cold spray barrier coating) while maintaining electrical and thermal conductivity. The components can include one or more exterior and/or interior surfaces coated with the electrically conductive cold spray barrier coating which is preferably corrosion resistant. In some embodiments, the entire exterior surface of the component may include the cold spray barrier coating.

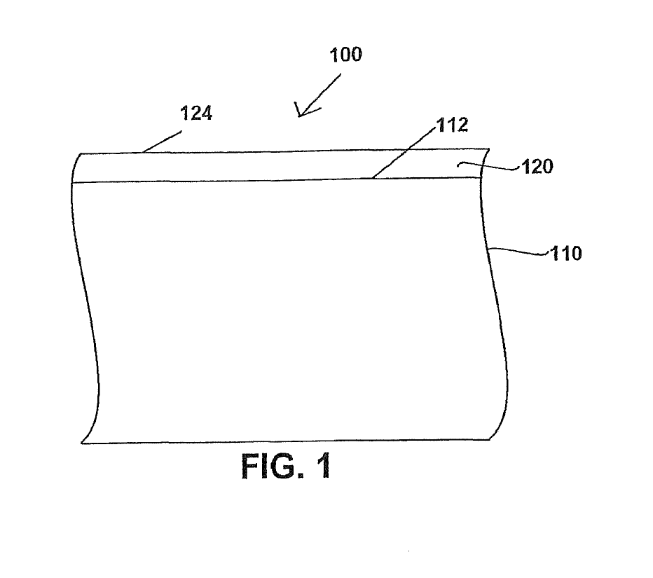

A cold spray coated component 100 according to an exemplary embodiment is shown in FIG. 1. As shown, the component 100 is a substrate 110 including a surface 112 and an electrically conductive cold spray barrier coating 120 formed on the surface 112 such that it forms an outer surface 124 of the component 100. The substrate 110 may preferably be formed entirely of aluminum or an aluminum alloy (e.g., AL 6061), or alternatively may be formed from a composite of a conductive material, a dielectric material, or an insulator wherein the substrate 110 has at least one surface 112 forming an electrical contact formed from a metal, such as aluminum or an aluminum alloy. If entirely of aluminum or an aluminum alloy, the substrate 110 can be wrought, extruded, or cast aluminum. Preferably, the surface 112 of the substrate 110 to be cold spray barrier coated is bare (non-anodized) aluminum. In alternative embodiments, the aluminum or aluminum alloy surface may be anodized and/or roughened. In further preferred embodiments, the aluminum or aluminum alloy surface may be polished or machined

The cold spray barrier coating 120 is preferably formed by cold spraying a metal, ceramic, or a metal ceramic compound onto the at least one metal surface 112 forming an electrical contact of the substrate 110. Cold spraying is a kinetic spray process utilizing supersonic jets of compressed gas to accelerate near-room temperature powder particles (here, preferably of high purity aluminum, or alternatively tantalum) at high velocities, wherein the particles traveling at speeds between about 450 to 1,500 msec impact with the substrate (here, the metal component or other product being cold spray barrier coated) to create a coating. In one embodiment, the particles plastically deform and consolidate on the substrate upon impact. Cold spray may also be referred to as gas dynamic spray, supersonic spray, and/or kinetic spray. The basis of the cold spray process is the gas-dynamic acceleration of particulates (from high purity metal powders) to supersonic velocities (450-1500 m/sec), and hence high kinetic energies, so that solid-state plastic deformation and fusion occur on impact to produce dense coatings, with refined microstructure, without the feedstock material being significantly heated. For example, pure aluminum which has been wrought (fully worked) may have a Brinell Hardness Scale value between about 40 and 45, whereas cold sprayed pure aluminum may have a Brinell Hardness scale value between about 55 and 60. In one embodiment, this may be achieved using convergent-divergent de Laval nozzles, high pressures (up to 500 psi or 3.5 MPa) and flow rates (up to 90 m³/hr) of compressed gases such as helium, argon, or nitrogen. In another embodiment, the gases may be pre-heated to (below the melting point of many metals, preferably below 120° C.) increase the velocity of the particles of the coating material. In one embodiment, the particles of the metallic bonding material (here, the high purity aluminum) may have a particle diameter ranging from about 1 to about 50 microns, and a particle density ranging from about 2.5 g/cm³ to about 20 g/cm³.

As the gas with which the metal powder forms a gas-powder mixture there is generally used an inert gas. Inert gas according to the embodiments herein includes, but is not limited to argon, helium, or relatively non-reactive nitrogen or mixtures of two or more thereof. In particular cases, air may also be used. If safety regulations are met, the use of mixtures of hydrogen with other gases can be considered and can be used advantageously due to hydrogen's extremely high sonic velocity. In fact hydrogen's sonic velocity is 30% greater than that of helium which in turn is approximately 3 times that of nitrogen. Air's sonic velocity is 344 m/s at 20 C and 1 atmosphere (atm), while hydrogen with a lower molecular weight (about 2.016 as compared to air's molecular weight of 28.96) has a sonic velocity of 1308 m/s. For example, a gas mixture of helium and 4% hydrogen may be utilized.

The cold spray barrier coating forming the electrically conductive coating is preferably formed from a metallic material, wherein the metallic material is preferably corrosion resistant to halogen containing gas species. The coating can be formed niobium, tantalum, tungsten, tungsten carbide, molybdenum, titanium, zirconium, nickel, cobalt, iron, chromium, aluminum, silver, copper, stainless steel, WC-Co, or mixtures thereof. Preferably, the cold spray barrier coating is formed from aluminum and is formed to coat an aluminum surface which functions as an electrical contact in the plasma chamber. During processing the previously applied aluminum cold spray barrier coating formed on the aluminum surface which functions as an electrical contact may be eroded, and in such an instance, a new aluminum cold spray barrier coating may be applied on the electrical contact such that the life of the electrical contact in the plasma chamber may be extended.

In one embodiment, the cold spray deposition may be performed in an inert chamber atmosphere, such as a vacuum chamber comprising argon, in order to prevent the oxidation of the substrate, for example an aluminum substrate, that is to be sprayed. On the other hand, in another embodiment, the cold spray deposition may be performed in air (e.g., in the room atmosphere), thereby allowing the spraying process to occur in a continuous, in-line fashion (i.e., without the substrate leaving the manufacturing line). An in-line spraying process may reduce the total amount of time and cost associated with the manufacture of the high purity spray coated substrates according to the teachings of one embodiment of the present disclosure.

The cold spray barrier coating forming the electrically conductive cold spray barrier coating 120 can have a thickness of about 1 micrometer to about 10,000 micrometers, such as about 2 micrometers to about 15 micrometers. Preferably, the thickness of the cold spray barrier coating is substantially uniform over the surface 112 of the substrate 110. In general, the cold spray barrier coating has a purity of at least 99%, such as 99.5% or 99.7%, 99.9%, advantageously has a purity of at least 99.95%, based on metallic impurities, especially of at least 99.995% or of at least 99.999%, in particular preferably of at least 99.9995%.

The cold spray barrier coating is preferably very dense with less than about 5% by volume porosity. In more preferable embodiments, the cold spray barrier coating has less than about 2% by volume porosity, or less than about 1% by volume porosity, such as a porosity of less than about 0.5%, 0.1%, 0.01%, 0.001%, and 0.0001% i.e., has a density that approaches the theoretical density of the coating material. The cold spray barrier coating is preferably also free of defects. A low porosity level can minimize contact of aggressive plasma etch (e.g., plasma formed from fluorocarbon, fluorohydrocarbon, bromine, and chlorine containing etch gases) atmospheres with the underlying substrate. Accordingly, the cold spray barrier coating protects against physical and/or chemical attack of the substrate by such aggressive atmospheres.

In general if an alloy is used instead of a pure metal for the cold spray barrier coating, then preferably the alloy as a whole, has high purity, so that a corresponding highly pure coating can be produced. In one of the embodiments disclosed herein the total content of non-metallic impurities in powders, such as oxygen, carbon, nitrogen or hydrogen, should advantageously be less than 1,000 ppm, preferably less than 500 ppm, and more preferably less than 150 ppm. In one of the embodiments disclosed herein, the oxygen content is 50 ppm or less, the nitrogen content is 25 ppm or less and the carbon content is 25 ppm or less. The content of metallic impurities is advantageously 500 ppm or less, preferably 100 ppm or less and most preferably 50 ppm or less, in particular 10 ppm or less. The oxygen content of the cold spray barrier coating is largely dependent on the oxygen content of the original powder used to perform the cold spraying as opposed to the cold spraying process.

The cold spray barrier coating forming the electrically conductive and preferably corrosion resistant coating 120 preferably has good adhesion strength to the surfaces 112 of the substrate 110 (i.e. fails cohesively). The cold spray barrier coating can be formed directly on the substrate 110 without having previously roughened the substrate surface 112. In an alternate embodiment the substrate surface 112 may be roughened before the cold spray barrier coating is applied. In a preferred embodiment, the cold spray barrier coating provides suitable adherence without prior roughening of the substrate surface 112, which obviates additional process steps. Preferably, the cold spray barrier coating has a sufficiently-high adhesive bond strength to the surface(s) 112 of a substrate 110 on which the coating is formed such that when a tensile bond strength test is performed on the component 100, the cold spray barrier coating fails cohesively (i.e., in the substrate bulk of the component) and not adhesively (i.e., at the substrate/coating interface).

In order to ensure good adhesion of the cold spray barrier coating to the substrate 110, the substrate surface 112 should be thoroughly cleaned from oxide scale and/or grease, prior to cold spraying. This cleaning can be carried out by agitating the substrate 110 in a solution of dilute hydrochloric acid, or sulfuric acid, or in a degreasing solvent.

Embodiments of the cold spray coated component may be used in plasma etch chambers or deposition chambers of semiconductor plasma processing apparatuses, such as dielectric etch chambers, capacitively coupled plasma etching chambers, inductively coupled plasma etching chambers, PECVD (plasma enhanced chemical vapor deposition) chambers, and ALD (atomic layer deposition) chambers for example. In these chambers, substrate surfaces can be exposed to plasma and/or process gases. In certain etching processes, these process gases can be halogen-containing species, e.g., CₓF_{y}, CₓH_{y}F_{z}, HBr, NF₃, HCl, SiCl₄, Cl₂, and BCl₃, which are corrosive with respect to certain materials, such as aluminum and aluminum alloy surfaces. The cold spray barrier coating, however, can be used to coat the plasma-exposed and/or process gas exposed aluminum or aluminum alloy surfaces to provide corrosion resistance from the plasma and process gases. The cold spray barrier coating may be used to provide, for example, a dense aluminum coating, wherein the coating may be replaced periodically after being eroded and/or corroded to a predetermined point. Alternatively, the cold spray barrier coating may be used to provide a dense tantalum coating. Tantalum is preferred due to its resistance to corrosive gas attacks at high temperature and pressure as well as for desired electrical and thermal conductivity properties. Preferably the plasma-exposed and/or process gas exposed aluminum or aluminum alloy surfaces in the plasma processing apparatus include the cold spray barrier coating wherein a portion of the coated surfaces can form electrical and thermal contact surfaces wherein electrical current and thermal energy may be conducted therethrough. The cold spray barrier coating may provide corrosion resistance to the exposed surfaces while not inhibiting electrical conduction or interfering with an RF return path provided by the component in a semiconductor plasma processing apparatus.

Although the cold spray barrier coating is applicable to any type of component having a metal surface forming an electrical contact, for ease of illustration, the coating will be described in more detail with reference to the apparatus described in commonly-assigned U.S. Published Application No. 2009/0200269 which is incorporated herein by reference in its entirety.

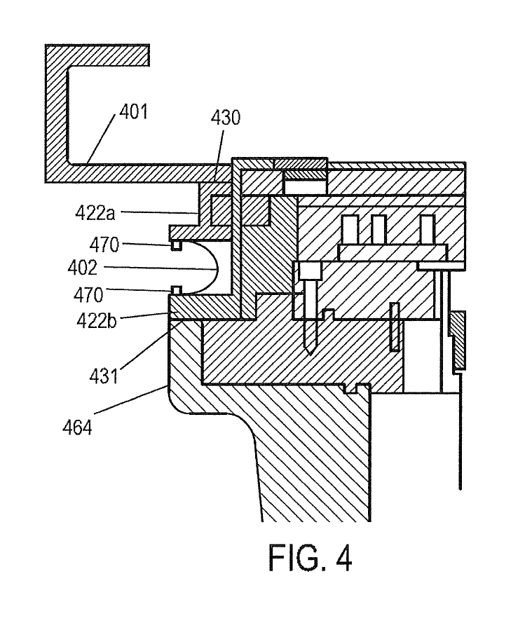

FIG. 2 shows an exemplary embodiment of an adjustable gap capacitively-coupled plasma (CCP) etching chamber 200 (“chamber”) of a plasma processing apparatus. The chamber 200 includes chamber housing 202; an upper electrode assembly 225 mounted to a ceiling 228 of the chamber housing 202; a lower electrode assembly 215 (i.e. substrate support) mounted to a floor 205 of the chamber housing 202, spaced apart from and substantially parallel to the lower surface of the upper electrode assembly 225; a confinement ring assembly 206 surrounding a gap 232 between the upper electrode assembly 225 and the lower electrode assembly 215; an upper chamber wall 204; and a chamber top 230 enclosing the top portion of the upper electrode assembly 225. In an alternative embodiment, an annular shroud 401 (see FIG. 4) may replace the confinement ring assembly 206 such that the annular shroud 401 surrounds the gap 232 between the upper electrode assembly 225 and the lower electrode assembly 215.

The upper electrode assembly 225 preferably includes an upper showerhead electrode 224 and a gas distribution plate 226. The upper electrode assembly 225 may also optionally include an outer electrode 224a surrounding the upper showerhead electrode 224 as well as an optional gas distribution ring 226a surrounding the gas distribution plate 226. The upper showerhead electrode 224 and gas distribution plate 226 include gas passages for distributing process gas into the gap 232 defined between the upper showerhead electrode 224 and the lower electrode assembly 215. The upper electrode assembly 225 may further optionally include a gas distribution system such as one or more baffles (not shown) including gas passages for distributing process gas into the gap 232 defined between the upper showerhead electrode 224 and the lower electrode assembly 215. An exemplary embodiment of an upper electrode assembly which includes baffles can be found in commonly-assigned U.S. Pat. No. 8,313,665, which is hereby incorporated by reference in its entirety. The upper electrode assembly 225 can include additional components such as RF gasket 320, a heating element 121, gas nozzle 122, and other parts. The chamber housing 202 has a gate (not shown) through which a substrate 214, is unloaded/loaded into the chamber 200. For example, the substrate 214 can enter the chamber through a load lock as described in commonly-assigned U.S. Pat. No. 6,899,109, which is hereby incorporated by reference in its entirety.

The upper showerhead electrode 224 is preferably formed from a semiconductor compatible material such as single crystal silicon or polysilicon. The gas distribution plate is preferably formed from aluminum or an aluminum alloy. Preferably, the gas distribution plate 226 and showerhead electrode 224 are configured such that they may conduct heat and direct RF current therethrough. Aluminum or aluminum alloy surfaces on the gas distribution plate 226 which interface with the silicon upper showerhead electrode 224 form electrical contacts therebetween. The portions of the aluminum or aluminum alloy surfaces of the gas distribution plate 226 are preferably coated with the cold spray barrier coating to provide a metal coated component exhibiting good electrical and thermal conductivity. In an embodiment, an electrically conductive member, such as RF gasket 320 is in direct contact with the gas distribution plate 226 and showerhead electrode 224. The RF gasket 320 is mounted near the peripheral edge of the gas distribution plate 226 and showerhead electrode 224 to improve RF conduction. Additionally, the RF gasket 320 improves DC conduction between the gas distribution plate 226 and showerhead electrode 224, preventing arcing between these two components. Preferably, the RF gasket 320 is flexible, such that it can accommodate the contraction and expansion due to thermal cycling of the upper electrode assembly 225. The RF gasket 320 is preferably a spiral metallic gasket, and is preferably made of stainless steel, aluminum, an aluminum alloy, or the like. The RF gasket 320 is preferably cold sprayed with the cold spray barrier coating such as to farm a corrosion resistant and electrically conductive cold spray barrier coated component which may conduct heat as well.

In some exemplary embodiments, the upper electrode assembly 225 is adjustable in up and down directions (arrows A and A′ in FIG. 2) to adjust the gap 232 between the upper and lower electrode assemblies 225/215. An upper assembly lift actuator 256 raises or lowers the upper electrode assembly 225. In the illustration, annular extension 229 extending vertically from the chamber ceiling 228 is adjustably positioned along cylindrical bore 203 of the upper chamber wall 204. A sealing arrangement (not shown) may be used to provide a vacuum seal between 229/203, while allowing the upper electrode assembly 225 to move relative to the upper chamber wall 204 and lower electrode assembly 215. A RF return strap 248 electrically couples the upper electrode assembly 225 and the upper chamber wall 204 such that direct current may be conducted therethrough.

The RF return strap 248 provides a conductive RF return path between the upper electrode assembly 225 and the upper chamber wall 204 to allow the electrode assembly 225 to move vertically within the chamber 200. The strap includes two planar ends connected by a curved section. The curved section accommodates movement of the upper electrode assembly 225 relative to the upper chamber wall 204. Depending on factors such as the chamber size, a plurality (2, 4, 6, 8, 10 or more) RF return straps 248 can be arranged at circumferentially spaced positions around the upper electrode assembly 225. Additionally, a plurality (2, 4, 6, 8, 10 or more) RF return straps 246 can be arranged at circumferentially spaced positions around the lower electrode assembly 215

For brevity, only one gas line 236 connected to gas source 234 is shown in FIG. 2. Additional gas lines can be coupled to the upper electrode assembly 225, and the gas can be supplied through other portions of the upper chamber wall 204 and/or the chamber top 230.

In other exemplary embodiments, the lower electrode assembly 215 may move up and down (arrows B and B′ in FIG. 2) to adjust the gap 232, while the upper electrode assembly 225 may be stationary or movable. FIG. 2 illustrates a lower assembly lift actuator 258 connected to a shaft 260 extending through the floor (bottom wall) 205 of the chamber housing 202 to a lower conducting member 264 supporting the lower electrode assembly 215. A bellows 262 forms part of a sealing arrangement to provide a vacuum seal between the shaft 260 and the floor 205 of the chamber housing 202, while allowing the lower electrode assembly 215 to move relative to the upper chamber wall 204 and upper electrode assembly 225 when the shaft 260 is raised and lowered by the lower assembly lift actuator 258. If desired, the lower electrode assembly 215 can be raised and lowered by other arrangements. For example, another embodiment of an adjustable gap capacitively coupled plasma processing chamber which raises and lowers the lower electrode assembly 215 by a cantilever beam is disclosed in commonly-assigned U.S. Pat. No. 7,732,728, which is hereby incorporated by reference in its entirety.

If desired, the movable lower electrode assembly 215 can be grounded to a wall of the chamber by at least one lower RF strap 246 which electrically couples an outer edge ring (ground ring) 222 to an electrically conductive part, such as a chamber wall liner 252 and provides a short RF return path for plasma, while allowing the lower electrode assembly 215 to move vertically within the chamber 200 such as during multistep plasma processing wherein the gap is set to different heights.

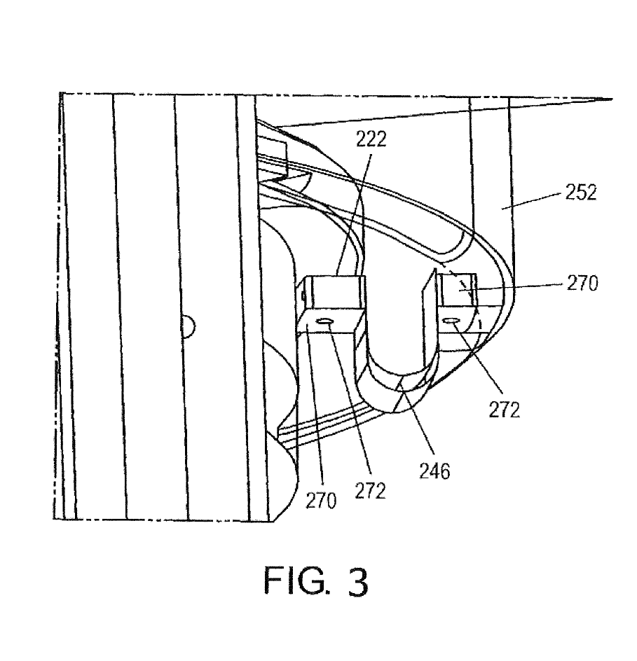

FIG. 3 illustrates an embodiment of a flexible and conductive RF strap 246 electrically connecting the outer edge ring 222 to an electrically conductive chamber sidewall liner 252 in an adjustable gap capacitively-coupled plasma etching chamber 200. Electrically conductive connecting members 270 may be formed from aluminum or aluminum alloy metal blocks or aluminum or aluminum alloy plated metal blocks, wherein a first electrically conductive connecting member 270 connects a first end of the RF strap 246 to the electrically conductive chamber sidewall liner 252 and a second electrically conductive connecting member 270 connects a second end of the RF strap 246 to the outer edge ring 222 such that heat and electricity may be conducted therethrough. The electrically conductive connective members 270, the RF strap 246, the outer edge ring 222, and the electrically conductive chamber sidewall liner 252 may each have the cold spray barrier coating on metal surfaces thereof wherein a portion of each metal surface is configured to form an electrical contact. Additionally, plasma-exposed and/or process gas exposed aluminum or aluminum alloy surfaces of the electrically conductive connective members 270, the RF strap 246, the outer edge ring 222, and the electrically conductive chamber sidewall liner 252 may include the cold spray barrier coating. Preferably plasma-exposed and/or process gas exposed aluminum or aluminum alloy surface areas include the cold spray barrier coating such that the portions of the metal surfaces forming electrical contacts between the connecting members 270 and/or the flexible RF strap 246 as well as plasma exposed and/or process gas exposed aluminum or aluminum alloy surface areas adjacent to the electrical contacts are protected from radicals by the cold spray barrier coating while maintaining high thermal and electrical conductivity such that electrical current may be conducted therethrough. Fastener holes 272 may be provided in the connecting members 270 adapted to accept fasteners such as screws, rivets, pins, and the like to complete the connections between the connecting members 270 and the RF strap 246. The fasteners may be formed from aluminum or an aluminum alloy or alternatively may be aluminum or aluminum alloy plated fasteners. To protect the fasteners from exposure to the oxygen and/or fluorine radicals, the cold spray barrier coating can also be provided on plasma-exposed and/or process gas exposed surfaces of the aluminum fasteners.

In the embodiment shown in FIG. 2, the lower conducting member 264 is electrically connected to an outer edge ring (ground ring) 222 which surrounds dielectric coupling edge ring 220 which electrically insulates the outer edge ring 222 from the lower electrode assembly 215. The lower electrode assembly 215 includes chuck 212, edge ring assembly 216, and a lower electrode 210. However, the lower electrode assembly 215 can include additional components, such as a lift pin mechanism for lifting the substrate, optical sensors, and a cooling mechanism for cooling the lower electrode assembly 215 attached to or forming portions of the lower electrode assembly 215. The chuck 212 clamps a substrate 214 in place on the top surface of the lower electrode assembly 215 during operation. The chuck 212 can be an electrostatic, vacuum, or mechanical chuck. Aluminum or aluminum alloy electrical contact surfaces comprised in the lower electrode assembly 215 may preferably include the cold spray barrier coating such that direct or RF current may be conducted therethrough.

For example, as illustrated in FIG. 4, an annular shroud 401 is electrically connected to an outer edge ring 422a at an electrical contact 430 therebetween. The outer edge ring 422a is electrically connected to a flexible and conductive RF strap 402 and the flexible and conductive RF strap 402 is electrically connected to an outer edge ring 422b. Electrically conductive connecting members 470 may be formed from aluminum or aluminum alloy metal blocks or aluminum or aluminum alloy plated blocks, wherein a first electrically conductive connecting member 470 connects a first end of the RF strap 402 to the outer edge ring 422a, and a second electrically conductive connecting member 470 connects a second end of the RF strap 402 to the outer edge ring 422b such that electrical current may be conducted therethrough. The outer edge ring 422b is electrically connected to a lower conducting member 464 at an electrical contact 431 therebetween. The annular shroud 401, the outer edge rings 422a, 422b, the flexible and conductive RF strap 402, and the electrically conductive aluminum or aluminum alloy blocks 470 may each include the cold spray barrier coating on mating surfaces thereof wherein the mating surfaces form electrical contacts therebetween. For example, the electrical contacts 430, 431 include the cold spray barrier coating. Additionally, the cold spray barrier coating is also included on plasma-exposed and/or process gas exposed aluminum or aluminum alloy surfaces adjacent the mating surfaces which than the electrical contacts.

Referring back to FIG. 2, the lower electrode 210 is typically supplied with RF power from one or more RF power supplies 240 coupled to the lower electrode 210 through an impedance matching network 238. The RF power can be supplied at one or more frequencies of, for example, 400 KHz, 2 MHz, 13.56 MHz, 27 MHz, and 60 MHz. The RF power excites the process gas to produce plasma in the gap 232. In some embodiments the upper showerhead electrode 224 and chamber housing 202 are electrically coupled to ground. In other embodiments the upper showerhead electrode 224 is insulated from the chamber housing 202 and supplied RF power from an RF supply through an impedance matching network.

The bottom of the upper chamber wall 204 is coupled to a vacuum pump unit 244 for exhausting gas from the chamber 200. Preferably, the confinement ring assembly 206 substantially terminates the electric fields formed within the gap 232 and prevents the electric fields from penetrating an outer chamber volume 268. The confinement ring assembly 206 can be grounded to a wall of the chamber by at least one flexible RF strap 250 which electrically couples the confinement ring assembly 206 to an electrically conductive part such as upper chamber wall 204. FIG. 1 shows a conductive chamber wall liner 252 supported via a horizontal extension 254. Preferably the horizontal extension 253 is electrically conductive. The RF strap(s) 250 preferably provide a short RF return path by electrically coupling the confinement ring assembly 206 to the horizontal extension 254 or alternatively the upper chamber wall 204. The RF strap(s) 250 can provide conductive paths between the confinement ring assembly 206 and the upper chamber wall 204 at various vertical positions of the confinement ring assembly 206 within the chamber 200. The metal portions of the RF strap(s) 250, confinement ring assembly 206, and upper chamber wall 204 which form electrical contacts therebetween (i.e. mating surfaces) preferably include the cold spray barrier coating. Further, plasma exposed and/or process gas exposed portions of the RF strap(s) 250, confinement ring assembly 206, and upper chamber wall 204 include the cold spray barrier coating.

Process gas injected into the gap 232 is energized to produce plasma to process the substrate 214, passes through the confinement ring assembly 206, and into outer chamber volume 268 until exhausted by the vacuum pump unit 244. Since plasma chamber parts in the outer chamber volume 268 can be exposed to plasma and reactive process gas (radicals, active species) during operation, aluminum or aluminum alloys forming a surface of said chamber part may preferably include the electrically conductive cold spray barrier coating that can withstand the plasma and reactive process gas. Preferably the cold spray barrier coating is formed from a corrosion resistant metal, such as tantalum. Alternatively the cold spray barrier coating may be formed from dense, highly pure aluminum.

In an embodiment the RF power supply 240 supplies RF power to the lower electrode assembly 215 during operation, the RF power supply 240 delivers RF energy via shaft 260 to the lower electrode 210. The process gas in the gap 232 is electrically excited to produce plasma by the RF power delivered to the lower electrode 210.

Plasma chamber substrates, which have at least one metal surface wherein a portion of the metal surface is configured to form an electrical contact, such as a portion of an aluminum or aluminum alloy surface(s) forming an electrical contact surface for gas distribution plate 226, gas distribution ring 226a, one or more optional baffles, the lower electrode assembly 215, edge rings, the annular shroud 401, and the chamber liner 252, upper chamber wall 204, chamber housing 202, RF gasket 320, electrically conductive connecting members 270, and fasteners may be cold spray barrier coated components. Any other substrate in the semiconductor plasma processing apparatus having a metal surface such as an aluminum or aluminum alloy surface, wherein a portion of the metal surface is configured to form an electrical contact may also include the cold spray barrier coating. Preferably, the cold spray barrier coating is applied to bare (nonanodized) aluminum surfaces of the aluminum components. The cold spray barrier coating can be coated on some or all of the plasma exposed and/or process gas exposed surfaces of the components. In an embodiment, the cold spray barrier coated aluminum components may have an outer oxide coating formed thereon.

While the invention has been described in detail with reference to specific embodiments thereof, it will be apparent to those skilled in the art that various changes and modifications can be made, and equivalents employed, without departing from the scope of the appended claims.

What is claimed is:

1. A cold spray barrier coated component of a semiconductor plasma processing chamber, the component comprising:
a substrate having at least one metal surface wherein a portion of the metal surface is configured to form an electrical contact; and
a cold spray barrier coating formed from a thermally and electrically conductive material at least on the metal surface configured to form the electrical contact.

2. The cold spray barrier coated component of claim 1, wherein the cold spray barrier coating is on a portion of the metal surface exposed to plasma and/or process gas.

3. The cold spray barrier coated component of claim 1, wherein the cold spray barrier coating is selected from the group consisting of niobium, tantalum, tungsten, tungsten carbide, molybdenum, titanium, zirconium, nickel, cobalt, iron, chromium, aluminum, silver, copper, stainless steel, WC-Co and mixtures thereof.

4. The cold spray barrier coated component of claim 1, wherein (a) the cold spray barrier coating has a thickness of about 1 micrometer to about 10,000 micrometers; or (b) the cold spray barrier coating has a thickness of about 2 micrometers to about 15 micrometers.

5. The cold spray barrier coated component of claim 1, wherein the oxygen content of the cold spray barrier coating is 50 ppm or less, the nitrogen content of the cold spray barrier coating is 25 ppm or less, and the carbon content of the cold spray barrier coating is 25 ppm or less.

6. The cold spray barrier coated component of claim 3, wherein the cold spray barrier coating has by weight at least about 99.9% purity with up to about 0.1% incidental impurities.

7. The cold spray barrier coated component of claim 1, wherein the substrate is a gas distribution plate, a chamber wall, a chamber wall liner, baffle, gas distribution ring, substrate support, edge ring, fastener, shroud, confinement ring, gasket, RF strap, or electrically conductive connecting member.

8. The cold spray barrier coated component of claim 1, wherein the cold spray barrier coating has (a) a porosity of less than about 5%; (a) a porosity of less than about 2%; (c) a porosity of less than about 1%; or (d) a porosity of less than about 0.5%.

9. The cold spray barrier coated component of claim 1, wherein the metal surface of the substrate is formed from aluminum or an aluminum alloy.

10. A process for cold spray barrier coating an electrical contact of a component of a semiconductor plasma processing chamber, the process comprising:
cold spraying an electrically conductive cold spray barrier on at least a portion of at least one metal surface of a substrate, wherein the portion of the metal surface is configured to form an electrical contact.

11. The process of claim 10, wherein the electrically conductive cold spray barrier is cold sprayed on a plasma exposed and/or process gas exposed portion of the component.

12. The process of claim 10, wherein the component is a gas distribution plate, a chamber wall, a chamber wall liner, baffle, gas distribution ring, substrate support, edge ring, fastener, shroud, confinement ring, gasket, RF strap, or electrically conductive connecting member.

13. The process of claim 10, wherein the component is a previously used component of a semiconductor plasma processing chamber and wherein the cold spraying is part of a process of refurbishing the used component.

14. The process of claim 10, wherein (a) the cold spray barrier coating has by weight at least about 99.9% purity with up to about 0.1% incidental impurities; (b) the cold spray barrier coating has a porosity of less than about 5%; (c) the cold spray barrier coating has a porosity of less than about 2%; (d) the cold spray barrier coating has a porosity of less than about 1%; (e) the cold spray barrier coating has a porosity of less than about 0.5%; (f) the cold spray barrier coating has a thickness of about 1 micrometer to about 10,000 micrometers; and/or (g) the cold spray barrier coating has a thickness of about 2 micrometers to about 15 micrometers.

15. A semiconductor plasma processing apparatus, comprising:
a plasma processing chamber in which semiconductor substrates are processed;
a process gas source in fluid communication with the plasma processing chamber for supplying a process gas into the plasma processing chamber;
an RF energy source adapted to energize the process gas into the plasma state in the plasma processing chamber;
and at least one cold spray barrier coated component according to claim 1 in the plasma processing chamber.

16. The semiconductor plasma processing chamber of claim 15, wherein the plasma processing chamber is a plasma etching chamber.

17. The semiconductor plasma processing chamber of claim 15, wherein the plasma processing chamber is a deposition chamber.

18. The semiconductor plasma processing chamber of claim 15, wherein the at least one cold spray barrier coated component is part of a showerhead electrode assembly.

19. A method of plasma processing a semiconductor substrate in the apparatus according to claim 15, comprising:
supplying the process gas from the process gas source into the plasma processing chamber;
applying RF energy to the process gas using the RF energy source to generate plasma in the plasma processing chamber; and
plasma processing a semiconductor substrate in the plasma processing chamber.

20. The method of claim 19, wherein the processing comprises plasma etching the substrate or performing a deposition process.
